(19) United States
(12) Patent Application Publication
(10) Pub. No.: US 2023/0026967 A1
(43) Pub. Date: Jan. 26, 2023

(54) A METHOD OF CONNECTING CIRCUIT ELEMENTS

(71) Applicant: PRAGMATIC PRINTING LIMITED, Sedgefield Durham (GB)

(72) Inventors: Ken WILLIAMSON, Sedgefield Durham (GB); Richard PRICE, Sedgefield Durham (GB); Scott WHITE, Sedgefield Durham (GB)

(21) Appl. No.: 17/792,440

(22) PCT Filed: Jan. 29, 2021
(86) PCT No.: PCT/GB2021/050212

§ 371 Date: Jul. 13, 2022

(30) Foreign Application Priority Data
Jan. 30, 2020 (GB) 2001316.5

(51) Int. Cl. H01L 23/538; G06K 19/077; H01L 21/48; H05K 1/18

(52) U.S. Cl. CPC H01L 23/5387; G06K 19/0775; G06K 19/07728; H01L 21/485; H01L 23/5382; H05K 1/189

(57) ABSTRACT

The present invention relates to a method of connecting circuit elements and a corresponding system for connecting circuit elements. The method includes providing a plurality of flexible circuit elements on a carrier element; forming a connecting structure. The formed connecting structure includes at least two contact points; and operative connections between each of the plurality of flexible circuit elements and the at least two contact points. The method further includes severing the operative connection between at least one of the plurality of flexible circuit elements and the at least two contact points.

The present invention relates generally to the field of electrical circuits and microchips and relates in particular to an improved method of connecting circuit elements, for example an Integrated Circuit (IC). It also relates to a system for connecting circuit elements. The project leading to this application has received funding from the European Union's Horizon 2020 research and innovation programme under grant agreement No 723879″.

### INTRODUCTION

A flexible circuit element or structure, such as, for example, a flexible integrated or printed circuit (i.e. IC), is a patterned arrangement of circuitry and components that utilises flexible base material with or without flexible over lay. The circuitry patterned on each flexible circuit element may comprise any of resistors, capacitors, transistors, diodes, inductors, conductors, etc. In particular, the flexible circuit structure (e.g. flexible IC, FlexIC) may be formed in a thin layer of soft polymer film so that the flexible circuit structure can be bent or even stretched while maintaining integrity and functionality of the integrated circuit. Also, in contrast to a rigid silicon wafer IC, flexible circuit structures have usually no further protection, such as a hard, outer plastic case, and may therefore be vulnerable to damage.

In general, the flexible ICs are manufactured on a rigid carrier element or substrate, for example a glass wafer. A larger number of flexible ICs may be manufactured on each carrier element (for example, around 5000 flexible ICs), the flexible ICs being closely packed together on the carrier element.

Prior to release from the carrier element, one or more electronic components, for example HF antennas or other off-chip connection structures, may each be coupled to a corresponding flexible IC located on the carrier element. However in some cases there may be a mis-match in the respective size of the flexible ICs (typically around 0.5 to 10 mm in length and width) and the electronic component (for example HF antennas are typically around 20-60 mm in length and width). The mis-match in size and close packing of the flexible ICs on the carrier element is such that most of the flexible ICs are wasted, since they cannot be connected to the relatively small number (typically around 10-50 antennas can fit on the surface of a single glass wafer) of electronic components. This limits the practical realisation of this approach in assembling antennas with flexible ICs.

In some instances the yield of flexible ICs may be less than 100%, so only a fraction of the antennas are attached to fully working flexible ICs. In addition, the properties of the flexible ICs may vary, such that the performance from the resulting antenna arrangement may vary and require matching to the circuit.

It is desirable to provide an improved way of coupling flexible ICs together, particularly in a manner that improves the yield of functional off-chip connections (i.e. connections between one or more flexible ICs and a separate electronic component).

US 2006/267771 A1, WO2010/044341 A1, WO2015/121298 A1 are related to the adjustment of ‘on-chip’ connections or properties.

### SUMMARY OF THE INVENTION

According to a first aspect of the present invention there is provided a method of connecting circuit elements, the method comprising:
providing a plurality of circuit elements (for example flexible circuit elements) on a carrier element;
forming a connecting structure, the connecting structure comprising:
   at least two contact points; and
   operative connections between each of the plurality of circuit elements and the at least two contact points; and
severing the operative connection between at least one of the plurality of circuit elements and the at least two contact points.

Aptly, the plurality of flexible circuit elements are flexible circuit elements. More aptly the plurality of flexible circuit elements are flexible integrated circuits.

Aptly, the plurality of flexible circuit elements each include a patterned arrangement of circuitry and components disposed on a flexible base material.

Aptly, the carrier element is a glass wafer or a silicon wafer.

Aptly, the electronic component is an antenna element, a lead frame, an interconnect structure or an application circuit.

Aptly, the plurality of flexible circuit elements are arranged into at least one row, the flexible circuit elements within each row being coupled in parallel to the at least two contact points.

Aptly, the connecting structure is formed by:
forming a passivation layer over the plurality of flexible circuit elements;
patterning windows in the passivation layer in positions corresponding to connection points for each of the plurality of flexible circuit elements;
depositing a conducting layer over the passivation layer, the conducting layer forming a via through each window in the passivation layer to a connection point of the corresponding flexible circuit element.

Aptly, the connecting structure is further formed by patterning the conducting layer to define:
the at least two contact points of the connecting structure; and
operative connections between the at least two contact points and the vias formed through each window of the passivation layer.

Aptly, the conducting layer is patterned by photolithography and/or etching.

Aptly, the connecting structure includes at least two busbar structures (i.e. a conducting busbar) or rails.

Aptly, the method further comprises the step of performing at least one functional test on the plurality of flexible circuit elements, wherein the operative connection to be severed is selected based on the outcome of the at least one functional test on the plurality of flexible circuit elements.

Aptly, the operative connection between the at least one of the plurality of flexible circuit elements and the at least two contact points is severed using a laser.

Aptly, the method further comprises the step of operatively coupling the at least two contact points of the connecting structure to an electronic component. That is, the method may be a method of coupling an electronic component to at least one flexible circuit element.

Aptly, the step of operatively coupling the at least two contact points of the connecting structure to an electronic component is undertaken prior to severing the operative connection between at least one of the plurality of flexible circuit elements and the at least two contact points.

Aptly, the step of operatively coupling the at least two contact points of the connecting structure to an electronic component is undertaken following the severing of the operative connection between at least one of the plurality of flexible circuit elements and the at least two contact points.

Aptly, the step of operatively coupling the at least two contact points of the connecting structure to an electronic component comprises:
depositing a further passivation layer over the connecting structure;
patterning windows in the further passivation layer in positions corresponding to the at least two contact points of the connecting structure; and
coupling the electronic component to the at least two contact points via the windows in the further passivation layer.

Aptly, the method further comprises the step of depositing the electronic component over, or onto, the further passivation layer.

Aptly, following the step of severing the operative connection between at least one of the plurality of flexible circuit elements and the at least two contact points, the flexible circuit elements that remain operatively connected to the at least two contact points are lifted, or decoupled, from the carrier element. That is, the circuit elements/chips that have an operative off-chip connection are lifted, or decoupled, from the carrier element.

According to a second aspect of the present invention there is provided a system for connecting circuit elements, the system comprising:
an assembly comprising:
   a plurality of circuit elements (for example flexible circuit elements) positioned on a carrier element;
   a connecting structure, the connecting structure comprising:
      at least two contact points; and
      operative connections between each of the plurality of circuit elements and the at least two contact points;
severing means, configured to sever the operative connection between at least one of the plurality of circuit elements and the at least two contact points.

Aptly, the plurality of circuit elements are flexible circuit elements. More aptly, the plurality of circuit elements are flexible integrated circuits.

Aptly, the carrier element is a glass wafer or a silicon wafer.

Aptly, the plurality of flexible circuit elements are arranged into at least one row, the flexible circuit elements within each row being coupled in parallel to the at least two contact points.

Aptly, the connecting structure comprises:
a passivation layer formed over the plurality of flexible circuit elements, the passivation layer having windows in positions corresponding to connection points for each of the plurality of flexible circuit elements; and
a conducting via through each window in the passivation layer to a connection point of the corresponding flexible circuit element.

Aptly, the connecting structure further comprises operative connections between the at least two contact points and the conducting vias formed through each window of the passivation layer.

Aptly, the connecting structure includes at least two busbar structures or rails.

Aptly, the severing means is a laser.

Aptly, the system further comprises an electronic component operatively coupled to the at least two contact points of the connecting structure.

Aptly, the electronic component is an antenna element, a lead frame, an interconnect structure or an application circuit.

Aptly, the assembly includes a further passivation layer over the connecting structure, the further passivation layer having windows therein in positions corresponding to the at least two contact points, and wherein the operative coupling between the at least two contact points and the electronic component is made through the windows in the further passivation layer.

Aptly, the system further comprises a controller for controlling the severing means.

Aptly, the controller is configured to select an operative connection to be severed based on the outcome of functional testing of the plurality of flexible circuit elements.

Aptly, the system further comprises testing means for functionally testing the plurality of flexible circuit elements.

According to a third aspect of the present invention there is provided an assembly for connecting circuit elements, comprising:
a plurality of flexible circuit elements positioned on a carrier element;
a connecting structure, the connecting structure comprising:
   at least two contact points; and
   at least one operative connection between one of the plurality of flexible circuit elements and the at least two contact points;
   at least one non-operative connection between another of the plurality of flexible circuit elements and the at least two contact points.

Aptly, the assembly further comprises an electronic component operatively coupled to the at least two contact points of the connecting structure.

Certain aspects of the present invention provide a method for connecting circuit elements. Certain aspects of the present invention allow the circuit elements to be connected in a manner such that the resulting electronic structure (including a circuit element or connected circuit elements) has a desired specification.

Certain aspects of the present invention provide a method of coupling an electronic component to at least one circuit element. In such aspects, the electronic component can be coupled to a circuit element, or a network of circuit elements, with the desired specification. In such aspects, the method can improve the yield of direct attachment to the electronic component (for example in situations where there is a varying yield throughout the circuit elements). This is particularly useful in situations where the circuit elements are being connected ‘on-wafer’ to an ‘off-chip’ structure that is larger than a circuit element.

The term Integrated Circuit (IC) used in this disclosure may be interpreted very broadly, and the nature of ICs and other products described may be extremely diverse. Any item comprising an electronic component and exhibiting some electronic activity is in scope. ICs may include but are not limited to digital ICs, analogue ICs, mixed-signal ICs, microprocessors, digital signal processors (DSPs), logic ICs, microcontrollers, interface ICs, programmable logic devices, application-specific ICs (ASICs), RFID ICs, RF ICs, memory ICs, sensors, power management circuits, operational amplifiers, data acquisition ICs, clock/timing ICs etc., but also any suitable passive electronic components.

Throughout the specification, the term “connected” is understood to mean a direct connection such as electrical, mechanical or magnetic connection between the things that are connected. The term “coupled” is understood to mean a direct or indirect connection (i.e. through one or more passive or active intermediary devices or components).

Unless otherwise specified, the use of ordinal adjectives, such as, “first”, “second”, “third” etc. merely indicate that different instances of like objects are being referred to and are not intended to imply that the objects so described must be in a given sequence, either temporally, spatially, in ranking or in any other manner. Orientation terminology, such as, “horizontal” is understood with respect to a plane parallel to the conventional plane or surface of a wafer or substrate, regardless of the orientation of the wafer or substrate. The term “vertical” may refer to a direction perpendicular to the horizontal as defined previously. Prepositions, such as, “on”, “side”, “higher”, “upper”, “lower”, “over”, “bottom” and “under” may be understood with respect to the conventional plane or surface being on the top surface of the wafer or substrate, regardless of the orientation of the electrical interconnects or the electronic package.

As used herein, the term “operative connection” refers to a physical connection between two components that allows communication therebetween during operation thereof. For example, an “operative connection” in the illustrated examples refers to a physical connection that allows electrical communication (that is the passage of an electrical signal) from a first component to a second component (for example between circuit elements, or between a circuit element, or circuit elements, and an electronic component).

As used herein, the term “off-chip connection” refers to a connection between a chip or integrated circuit and a separate electronic component (i.e. an ‘off-chip’ component). As indicated by the following examples, the separate electronic component may be an additional chip, network of chips or other component (for example an antenna element, a lead frame, an interconnect structure or an application circuit). It would be understood that connections within the circuitry present on a chip or integrated circuit would be considered ‘on-chip’ rather than ‘off-chip’.

### BRIEF DESCRIPTION OF THE DRAWINGS

Examples of the present invention will now be described hereinafter, by way of example only, with reference to the accompanying drawings in which:

FIG. 1 illustrates a plan view of an electronic structure including a plurality of circuit elements provided on a carrier element;

FIG. 2 illustrates a schematic of a system including the electronic structure of FIG. 1;

FIG. 3 illustrates an example of an electronic structure, such as that illustrated in FIG. 1 for which operative connections from some of the circuit elements have been severed;

FIG. 4a illustrates a side cross-sectional view of an electronic structure as shown in FIG. 1 during formation of operative connections from the plurality of circuit elements;

FIG. 4b illustrates a side cross-sectional view of an electronic structure as shown in FIG. 1 during formation of operative connections from the plurality of circuit elements; and

FIG. 5 illustrates the electronic structure of FIG. 1 coupled to an electronic component (specifically a HF antenna).

In the drawings like reference numerals refer to like parts.

### DETAILED DESCRIPTION OF THE PREFERRED EMBODIMENT(S)

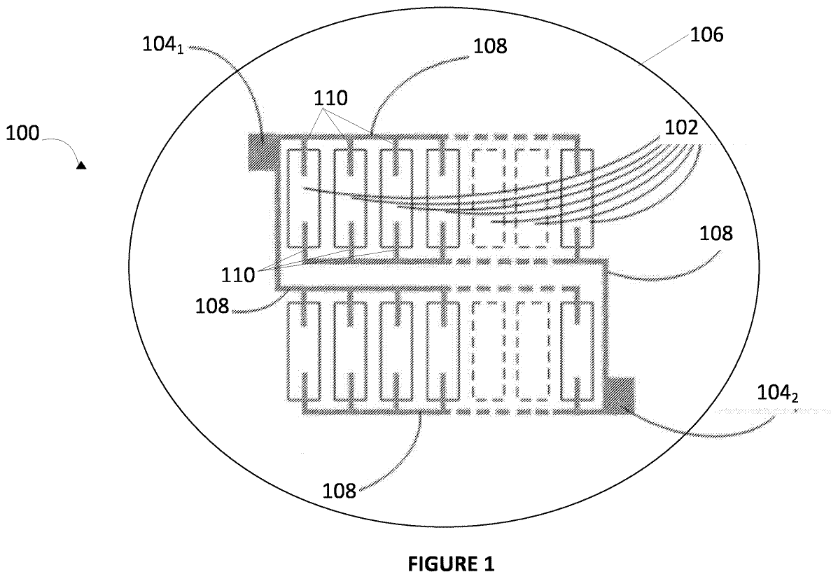

Referring now to FIG. 1, a first embodiment of an assembly or electronic structure 100 is illustrated. The assembly 100 includes a plurality of circuit elements 102 positioned on, or deposited/printed onto, a carrier element 106 (not shown to scale).

In this example the plurality of circuit elements 102 are flexible circuit elements, in particular flexible integrated circuits. For example, the flexible circuit elements may each include a patterned arrangement of circuitry and components disposed on a flexible base material (for example a thin layer of soft polymer film) with or without flexible over lay. The circuitry patterned on each flexible circuit element may comprise any of resistors, capacitors, transistors, diodes, inductors, conductors, etc. In this example, the carrier element 106 is a glass wafer.

The electronic structure 100 further includes a connecting structure, or a conducting structure. The connecting structure includes at least two contact or connection points 104. In this example, there are first and second contact points 104_{1,2}, which may for example be positive and negative terminal points for connection to corresponding terminals of an electronic component (such as a HF antenna or another off-chip connection structure or an application circuit). In other examples there may be multiple contact points—for example there may be an additional ground connection point and/or a communications block connection point or the like.

The connecting structure further includes operative connections 110 between each of the plurality of flexible circuit elements 102 and the contact points 104_{1,2}. In particular, each flexible circuit element 102 may include at least two connection points, with each connection point of the flexible circuit element being operatively connected to one of the contact points 104_{1,2}.

In this example, the plurality of flexible circuit elements 102 are arranged into rows, the flexible circuit elements 102 within each row being coupled in parallel to the two contact points 104_{1,2}. That is, the flexible circuit elements 102 within each row share a common connection to each of the two contact points 104_{1,2}.

There may be any number of flexible circuit elements 102 within each row. For example, there may be two, three, four or more flexible circuit elements 102 within each row. In general, the number of flexible circuit elements 102 within each row may only be limited by, for example, the specifics of the flexible circuit elements 102, the number of connections, the number of flexible circuit elements 102 on the carrier element/stepper field etc.

In this example two rows of flexible circuit elements 102 are illustrated, however in other examples, there may be any number of rows of flexible circuit elements 102 connected in parallel, for example.

In this example, the connecting structure includes at least two busbar structures 108 or rails. In particular, the common connection between the flexible circuit elements 102 within each row and each of the two contact points 104_{1,2} is provided by a busbar structure 108. More specifically, as shown in FIG. 1, the connecting structure includes two busbar structures 108 for each row of flexible circuit elements 102—that is, a busbar structure 108 for coupling each contact point 104_{1,2} to a corresponding connection point of each flexible circuit element within that row. In other words, for each row of flexible circuit elements 102, a first busbar structure 108 couples a first contact point 104₁ to a corresponding connection point of each flexible circuit element within that row and a second busbar structure 108 couples a second point 104₂ to a corresponding connection point of each flexible circuit element within that row. In this manner, each flexible circuit element includes separate operative connections to each contact point 104_{1,2}.

In general, the electronic structure 100 is configured to be operatively coupled to an electronic component. That is, an electronic component may be operatively coupled to the contact points 104_{1,2} of the busbar structures 108. For example, the electronic component may be an antenna element, a lead frame, an interconnect structure or an application circuit.

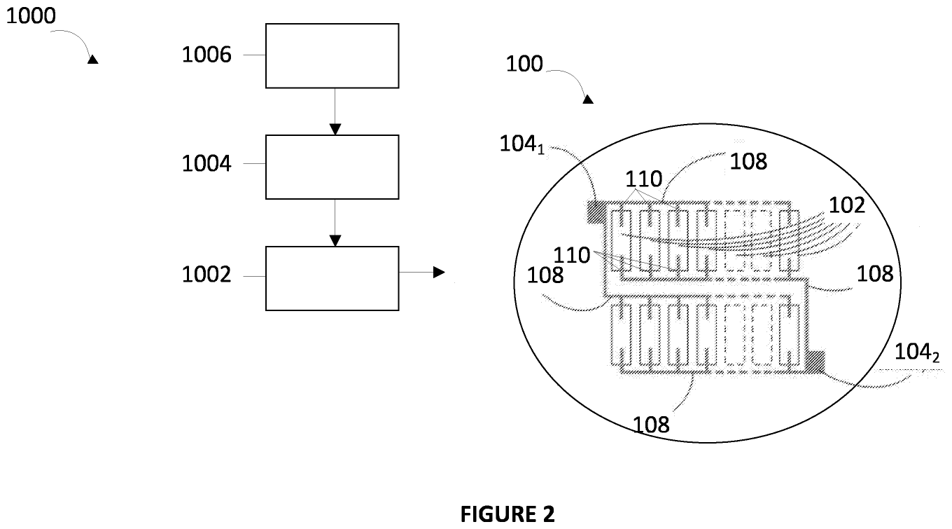

In this embodiment, as illustrated in FIG. 2, the electronic structure 100 is provided as part of a system 1000 for connecting circuit elements.

The system 1000 further includes a severing means 1002 configured to sever the operative connection between at least one of the plurality of flexible circuit elements 102 and the contact points 104_{1,2}.

That is, the system is in general used to connect flexible circuit elements in the following manner; the flexible circuit elements 102 are provided on the carrier element 106, the connecting structure (including the contact points 104_{1,2}, the busbar structures 108 and the operative connections 110) is formed on the carrier element 106 and then an operative connection 110, or multiple operative connections, between at least one of the plurality of flexible circuit elements 102 and the contact points 104_{1,2} is severed.

Any suitable severing means may be used, for example a laser. An IR (infra-red) laser is particularly advantageous in that the radiated energy is not absorbed by any passivation layers present and instead is absorbed by the conducting structure making up the operative connections. As such, the IR laser can be used through any passivation layers without the need for additional windows therethrough. Other suitable severing means may include mechanical severing means (such as milling or peeling apparatus) or chemical severing means (such as etching via lithography, either wet or dry, or printing).

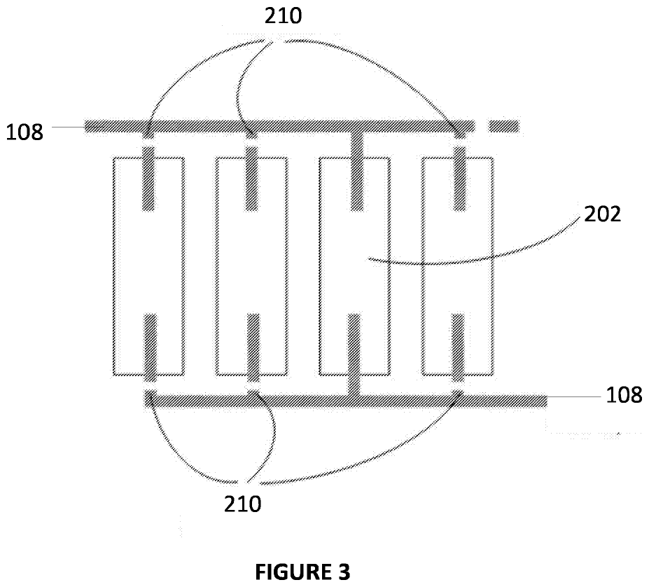

FIG. 3 illustrates a section of a row of flexible circuit elements where some of the operative connections 210 between the flexible circuit elements and the contact points (not shown) have been severed. In particular, the operative connections 210 have been severed by severing the connection between the flexible circuit element and the busbar structures 108.

In this example, the operative connection from one of the illustrated flexible circuit elements 202 to the busbar structure 108 remains intact (i.e. not severed). Within a row of flexible circuit elements any number of flexible circuit elements 202 may remain intact (or put another way, any number of the flexible circuit elements 202 may be severed) depending on the desired design parameters (for example, the desired impedances) of a resulting electronic structure. For example, the result may be a single flexible circuit element operatively connected to the busbar structures 108 for connection to an electronic component. In other examples, there may be two, three or more flexible circuit elements operatively connected to contact points 104_{1,2} arranged in one, two or more rows of flexible circuit elements.

In this example, the operative connection (or operative connections) to be severed is selected based on the outcome of functional testing of the plurality of flexible circuit elements 102 (i.e. a functional testing of each individual flexible circuit element 102). That is, at least one functional test may be carried out on each flexible circuit element 102 of the plurality of flexible circuit elements 102 prior to forming the connecting structure.

In this example, the system includes a controller 1004 for controlling the severing means 1002. The controller 1004 is configured to select an operative connection to be severed based on the outcome of the functional testing. In other words, the operative connections to be severed are predetermined based at least in part on the results of functional testing of each of the plurality of flexible circuit elements 102.

As used herein a functional test includes any test used to determine at least one parameter/property associated with a flexible circuit element or the performance thereof. For example, the functional test may determine the functionality of the flexible circuit element (i.e. if the flexible circuit element works/performs the desired function, for example logic functionality), an electrical property of the flexible circuit element (e.g. impedance, threshold voltage such as for analogue, interconnect resistances, all transistor parametrics, capacitance, interconnect resistances) or other aspects (e.g. bias-stress for stability/instability, resistance for timing, clock speed range, correct contents of a memory circuit, sensitivity of an input circuit, gain of an amplification circuit, calibration of an output circuit, or similar).

The functional test may measure a single datum or more complex data depending on the criteria or property being tested. Information obtained from the functional testing may be combined with, or supplemented by, data from other testing methods, for example visual inspection.

The functional testing may be carried out by testing means 1006 provided as part of the system 1000. For example, as indicated by the arrows in FIG. 2, the testing means 1006 may inform the controller 1004 (i.e. the testing means 1006 may supply the controller 1004 with information obtained from functional testing), which in turn instructs the severing means 1002.

Any suitable testing means may be used depending on the data to be obtained. For example, the testing means may include a prober for carrying out an electrical test via one or more connection points on each flexible circuit element 102, specifically those example connection points used to form the operative connection to the contact points 104_{1,2} of the connecting structure.

The testing means 1006 may be configured to test all of the flexible circuit elements 102 positioned on the carrier element 106 in a single testing operation. For example an automated test system may be used such as TEL Precio or WDF.

By using functional testing to inform the decision of which operative connections to sever the flexible circuit elements with desired properties can be chosen for an off-chip connection. Non-functional, or sub-specification, circuit elements can be ‘programmed out’ by severing the corresponding operative connection. For example, regardless of the yield of the flexible circuit elements on the carrier element (which may be less than 100%, for example 80%) a 100% yield can be achieved for connections made between flexible circuit elements and an off-chip electronic component. Similarly, undesirable circuits can be ‘programmed out’ such that the remaining flexible circuit elements have a desired specification for connection to an electronic component.

In other words, the combination of functional testing with a suitable severing means (for example a configurable laser) allows the choice of flexible circuit element to be responsive to the ‘as-manufactured’ specification thereof. In addition, the use of high throughput and high resolution techniques for production of the connecting structure (such as lithographic patterning) can still be used, despite the general inability of such techniques to produce features that differ from one assembly 100 to the next.

In use, the controller may use the results of the functional testing to select the operative connections to sever in any suitable manner. For example, a user may provide the controller with information related to the desired specification of the flexible circuit element or the network of flexible circuit elements and the controller may then search for the most suitable flexible circuit element or the flexible circuit elements that, together, are closest to the desired specification. The control means may then instruct the severing means accordingly.

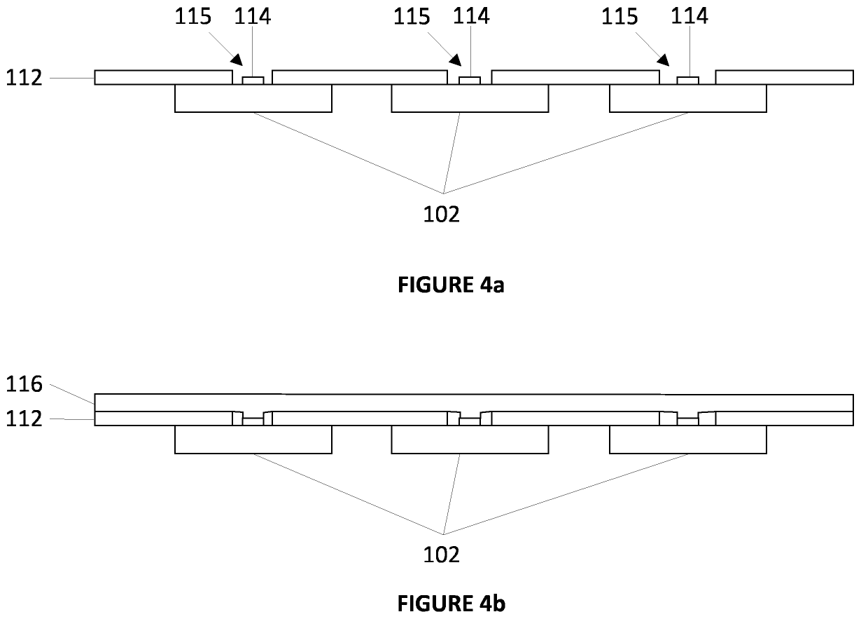

Herein an example is provided of the construction of the connecting structure used in the embodiment described above. In this example, the connecting structure includes at least one passivation layer 112, or insulation layer, formed (i.e. deposited or coated) over the plurality of flexible circuit elements 102 to prevent unwanted electrical connections between the flexible circuit elements 102 and the electrical component. Such an example is illustrated in FIG. 4a.

Suitable passivation layers 112 may comprise one or more layers of materials, including metal oxides such as Al2O3, ZrO2, HfO2, Y2O3, Si3N5, TiO2, Ta2O5; metal phosphates such as Al2POx; metal sulphates/sulphites such as HfSOx; metal nitrides such as AlN; metal oxynitride such as AlOxNy; inorganic insulators such as SiO2, Si3N4, SiNx; spin on glass (such as polyhydroxybenzyl silsesquioxane, HSQ), polymeric dielectric materials (such as Cytop®, a commercially available amorphous fluoropolymer), 1-Methoxy-2-propyl acetate (SU-8), benzocyclobutene (BCB), polyimide, polymethyl methacrylate, polybutyl methacrylate, polyethyl methacrylate, polyvinyl acetate, polyvinyl pyrrolidone, polyvinylphenol, polyvinylchloride, polystyrene, polyethylene, polyvinyl alcohol, polycarbonate, parylene, silicone; UV curable resins; Nanoimprint resists; or photoresists.

The dielectric material may have a relatively low dielectric constant (low-k, e.g. Cytop, HSQ, parylene) or a relatively high dielectric constant (high-k, e.g. Ta2O5, HfO2).

The passivation layer 112 may be applied to the carrier 106 by any suitable technique, e.g. physical deposition; physical vapour deposition (PVD); chemical deposition; chemical vapour deposition (CVD); atomic layer deposition (ALD); physical-chemical deposition; evaporation; sputtering; sol-gel techniques; chemical bath deposition; spray pyrolysis; pulsed laser deposition (PLD); solution processing; spin coating, slot die coating, printing.

In this example, the passivation layer 112 is provided as a ‘blanket’ coating in that it is formed over the entirety of the carrier element 106, therefore covering the flexible circuit elements provided thereon.

As shown, the passivation layer 112 includes windows 115 in positions corresponding to the connection points 114 for each of the plurality of flexible circuit elements 102. In this example, the windows 115 are patterned into the passivation layer 112 after the formation/deposition thereof. For example, the windows may be patterned into the passivation layer 112 using photolithography with a fixed mask. In other words, the windows are in predetermined or hard masked locations of the passivation layer corresponding to the connection points 114 for each of the plurality of flexible circuit elements 102.

Although in FIG. 4a the connection points 114 of the flexible circuit elements 102 are illustrated as protruding from an upper surface, this may be for illustrative purposes only. In general, the connection points 114 of the flexible circuit elements 102 may be formed in any suitable conducting layer of each flexible circuit element 102, for example an upper metal tracking layer or a metal redistribution layer.

The operative connections between the contact points 104_{1,2} of the connecting structure and the connection points 114 of each flexible circuit element 102 may be formed by depositing a conducting layer 116, for example by physical vapour deposition, over (i.e. onto) the passivation layer 112 as illustrated in FIG. 4b. In doing so, the conducting layer 116 forms a via through each window 115 in the passivation layer to the corresponding connection point 114 of a flexible circuit element 102. The conducting layer 116 is of a conducting material, such as a metal, such that the contact between the conducting layer 116 and the connection points 114 by way of the vias provides an electrical connection therebetween.

In other words, in this example, the connecting structure is formed by forming a passivation layer 112 over the plurality of flexible circuit elements 102; patterning windows 115 in the passivation layer 112 in positions corresponding to connection points 114 for each of the plurality of flexible circuit elements 102; depositing a conducting layer 116 over the passivation layer, the conducting layer 116 forming a via through each window 115 in the passivation layer 112 to a connection point 114 of the corresponding flexible circuit element.

The connecting structure may then be further formed, or further defined, by patterning the conducting layer 116, for example by photolithography (for example using fixed masks) and/or etching, to define the at least two contact points 104_{1,2} of the connecting structure; and the operative connections between the at least two contact points 104_{1,2} and the vias formed through each window 115 of the passivation layer 112. In other words, the structure of the contact points 104_{1,2}, the busbars 108 and the operative connections to the vias from the busbars 108 may be produced by patterning (i.e. removing material from) the conducting layer. Alternatively the conducting layer 116 of the connecting structure may be deposited by inkjet printing or another additive technique, enabling only the flexible elements 102 chosen for off-chip connection to be connected to the contact points 104_{1,2}. However this would lose the above-mentioned advantages associated with lithographic patterning techniques.

A further passivation layer (not shown) may be formed over the connecting structure. That is, a further passivation layer may be deposited onto, and subsequently cover, the connecting structure to prevent unwanted electrical connections between the connecting structure and the electrical component. The further passivation layer includes windows therein in positions corresponding to the contact points 104_{1,2} of the connecting structure. The operative coupling between the contact points 104_{1,2} and the electronic component can then be made through the windows in the further passivation layer. In this example, the further passivation layer and the windows patterned therein are formed in the same manner as the passivation layer 112 and windows 115.

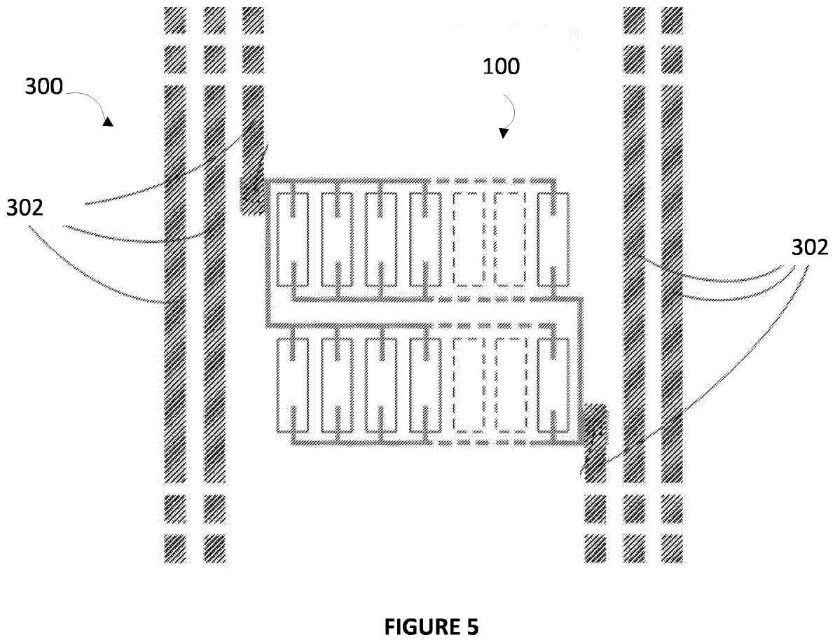

FIG. 5 illustrates the electronic structure 100 of FIG. 1, with an electronic component 300 coupled thereto via the contact points 104_{1,2}. In this example, the electronic component is a HF antenna deposited onto the further passivation layer (not shown) of the electronic structure 100. In this example, the HF antenna is deposited onto the electronic structure 100 as a series of windings 302. In depositing the antenna onto the further passivation layer, the antenna becomes operatively coupled to the contact points 104_{1,2} of the connecting structure through windows in the further passivation layer. The HF antenna may be deposited on to the electronic structure 100 in any suitable manner, for example by PVD, LIFT (laser induced forward transfer) or the like.

In this example, the electronic component is larger than the size of an individual flexible IC. For example, the flexible circuit elements may be about 0.5 to 10 mm in length and width and the electronic component (for example HF antennas) may be about 10-100 mm in length and width.

In the example of FIG. 5, the HF antenna is operatively coupled to the contact points 104_{1,2} of the connecting structure prior to severing any operative connections between the plurality of flexible circuit elements 102 and the contact points 104_{1,2}. That is, the off-chip connection can be made while the flexible circuit elements are still positioned on the carrier element and prior to the isolation of flexible circuit elements with the required specification.

Once the operative connections between the electronic component and the flexible circuit elements of the desired specification have been isolated (that is, following disconnection of below specification flexible circuit elements), the connected flexible circuit elements may be lifted from, or decoupled from, the carrier element. The electronic component and the flexible circuit elements may be singulated by conventional means, either prior to or following their decoupling from the carrier element.

In other examples, the step of operatively coupling the contact points 104_{1,2} of the connecting structure to an electronic component is undertaken following the severing of the operative connection between at least one of the plurality of flexible circuit elements and the at least two contact points. For example, where the electronic component is an application circuit to which interconnected flexible circuit elements are to be attached, the flexible circuit elements may be connected in parallel and the chosen connections severed as described above. Then the flexible circuit elements may be released from the carrier element and subsequently connected to the application circuit. That is, the flexible circuit elements can be parallelised on-wafer prior to the attachment to an application circuit. In such examples, the busbars themselves serve as a lead frame.

In further examples, the above described method may be used for selective interconnection in circuit architectures with redundant circuit elements where only a certain proportion need to yield, such as neural networks.

The flexible circuit elements of the above described examples may be otherwise termed a ‘chip’ or ‘flexible chip’. As such, the resulting assembly may be analogous to a multi-chip module or, following encapsulation, a system-in-package.

In some examples, the flexible circuit elements within the assembly may each be of the same ‘type’. In other examples, the assembly may include more than one type of flexible circuit element (for example, each row may comprise flexible circuit elements of a particular type). That is, an assembly may be provided with a first plurality of flexible circuit elements of a first type, a second plurality of flexible circuit elements of a second type and so on. Each plurality of flexible circuit elements may correspond to a ‘type’ of flexible circuit element or chip—for example the assembly may include a plurality of memory chips, a plurality of logic chips, a plurality of neural network chips and a plurality of analogue chips (or any combination thereof). Functional testing may be used to identify the best performing chip (or chips) of each type. The operative connection between the other chips and the contact points (or corresponding contact points) may be severed. Put another way, the chips of each type with lower performance can be selectively disconnected from the connecting structure/busbar. For example, for a given chip type the best n of m chips (where n<m) may be selected and the remaining chips of the m chips may be selectively disconnected from the connecting structure/busbar.

It will be apparent that, in many instances, the above-mentioned methods and systems may result in a number of flexible circuit elements remaining on the carrier element once the connecting structure, its connected flexible circuit elements and any connected electronic component have been decoupled from the carrier element. These remaining flexible circuit elements may be processed by the deposition and lithography methods described herein, so that a second connecting structure including new contact points 104 and busbars 108 is formed on top of the remaining flexible circuit elements, and connects to each connection point of those flexible circuit elements. In this way multiple rounds of flexible circuit element selection may be made, based upon the functional testing already performed. That is to say, the remaining flexible circuit elements may be connected to contact points 104 of a second (or third, etc.) connecting structure and then undesirable circuits can be ‘programmed out’ by severing their operative connections, such that the unsevered flexible circuit elements have a desired specification for connection to an electronic component. An additional antenna layer may be added, for example by PVD deposition and etching or screen printing and curing.

Alternatively, any unused flexible circuit elements may be decoupled from the carrier element by conventional means, for example by laser release then picked with a vacuum pick prior to or following singulation. In some examples non-functional flexible circuit elements may be ‘inked’ so as to mark them as not used.

In some examples, the passivation layer and further passivation layer may be formed as a multi-level passivation layer with in-built channels for the connecting structure to pass through. This would allow the structure to be planar. Such a structure could be formed by electroless plating (e.g. print catalyst/electroplate) or by using top metallisation on the FlexIC to initiate electroless plating.

It will be clear to a person skilled in the art that features described in relation to any of the embodiments described above can be applicable interchangeably between the different embodiments. The embodiments described above are examples to illustrate various features of the invention.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

1. A method of connecting circuit elements, the method comprising:
providing a plurality of flexible circuit elements on a carrier element;
forming a connecting structure, the connecting structure comprising:
at least two contact points; and
operative connections between each of the plurality of flexible circuit elements and the at least two contact points; and
severing the operative connection between at least one of the plurality of flexible circuit elements and the at least two contact points.

2. A method as claimed in claim 1, wherein the plurality of flexible circuit elements are flexible integrated circuits, and each include a patterned arrangement of circuitry and components disposed on a flexible base material, and wherein the plurality of flexible circuit elements are arranged into at east one row, the flexible circuit elements within each row being coupled in parallel to the at least two contact points.

3-4. (canceled)

5. A method as claimed in claim 1, wherein the connecting structure is formed by:
forming a passivation layer over the plurality of flexible circuit elements;
patterning windows in the passivation layer in positions corresponding to connection points for each of the plurality of flexible circuit elements;
depositing a conducting layer over the passivation layer, the conducting layer forming a via through each window in the passivation layer to a connection point of the corresponding flexible circuit element.

6. A method as claimed in claim 5, wherein the connecting structure is further formed by patterning the conducting layer to define:
the at least two contact points of the connecting structure; and
operative connections between the at least two contact points and the vias formed through each window of the passivation layer, and wherein the conducting layer is patterned by photolithography and/or etching.

7. (canceled)

8. A method as claimed in claim 1, wherein the connecting structure includes at least two busbar structures or rails.

9. A method as claimed in claim 1, wherein the method further comprises the step of performing at least one functional test on the plurality of flexible circuit elements, wherein the operative connection to be severed is selected based on the outcome of the at least one functional test on the plurality of flexible circuit elements.

10. A method as claimed in claim 1, wherein the operative connection between the at least one of the plurality of flexible circuit elements and the at least two contact points is severed using a laser.

11. A method as claimed in claim 1, further comprising the step of operatively coupling the at least two contact points of the connecting structure to an electronic component.

12. A method as claimed in claim 11, wherein the step of operatively coupling the at least two contact points of the connecting structure to an electronic component is undertaken prior to severing the operative connection between at least one of the plurality of flexible circuit elements and the at least two contact points.

13. A method as claimed in claim 11, wherein the step of operatively coupling the at least two contact points of the connecting structure to an electronic component is undertaken following the severing of the operative connection between at least one of the plurality of flexible circuit elements and the at least two contact points.

14. A method as claimed in claim 11, wherein the step of operatively coupling the at least two contact points of the connecting structure to an electronic component comprises:
depositing a further passivation layer over the connecting structure;
patterning windows in the further passivation layer in positions corresponding to the at least two contact points of the connecting structure; and
coupling the electronic component to the at least two contact points via the windows in the further passivation layer.

15. A method as claimed claim 1, wherein following the step of severing the operative connection between at least one of the plurality of flexible circuit elements and the at least two contact points, the flexible circuit elements that remain operatively connected to the at least two contact points are lifted, or decoupled, from the carrier element.

16. A system for connecting circuit elements, the system comprising:
an assembly comprising:
a plurality of flexible circuit elements positioned on a carrier element;
a connecting structure, the connecting structure comprising:
at least two contact points; and
operative connections between each of the plurality of flexible circuit elements and the at least two contact points;
severing means, configured to sever the operative connection between at least one of the plurality of flexible circuit elements and the at least two contact points.

17. A system as claimed in claim 16, wherein the plurality of flexible circuit elements are arranged into at least one row, the flexible circuit elements within each row being coupled in parallel to the at least two contact points.

18. A system as claimed claim 16, wherein the connecting structure comprises:
a passivation layer formed over the plurality of flexible circuit elements, the passivation layer having windows in positions corresponding to connection points for each of the plurality of flexible circuit elements; and
a conducting via through each window in the passivation layer to a connection point of the corresponding flexible circuit element, and wherein the connecting structure further comprises operative connections between the at least two points of the connecting structure and the conducting vias formed through each window of the passivation layer, and wherein the connecting structure includes at least two busbar structures or rails.

19. (canceled)

20. A system as claimed in claim 16, further comprising an electronic component operatively coupled to the at least two contact points of the connecting structure, and wherein the electronic component is an antenna element, a lead frame, an interconnect structure or an application circuit.

21-23. (canceled)

24. A system as claimed in claim 16,
wherein the assembly includes a further passivation layer over the connecting structure, the further passivation layer having windows therein in positions corresponding to the at least two contact points of the connecting structure, and
wherein the operative coupling between the at least two contact points and the electronic component is made through the windows in the further passivation layer.

25. A system as claimed claim 16, wherein the system further comprises a controller for controlling the severing means.

26. A system as claimed in claim 25, wherein the controller is configured to select an operative connection to be severed based on the outcome of functional testing of the plurality of flexible circuit elements.

27. A system as claimed claim 16, wherein the system further comprises testing means for functionally testing the plurality of flexible circuit elements.
